(19) United States
(12) Patent Application Publication
(10) Pub. No.: US 2026/0198057 A1
(43) Pub. Date: Jul. 9, 2026

(54) Capacitance structure and manufacturing method thereof

(71) Applicant: UNITED MICROELECTRONICS CORP., Hsin-Chu City (TW)

(72) Inventors: Chien-Hsien Chen, Hsinchu County (TW); Hui-Sheng Chang, Hsinchu City (TW)

(73) Assignee: UNITED MICROELECTRONICS CORP, Hsin-chu City (TW)

(21) Appl. No.: 19/044,632

(22) Filed: Feb. 4, 2025

(30) Foreign Application Priority Data
Jan. 3, 2025 (TW) 114100251

(51) Int. Cl. H10D 64/23; H10D 1/00; H10D 1/62

(52) U.S. Cl. CPC H10D 64/23; H10D 1/045; H10D 1/62

(57) ABSTRACT

The invention provides a capacitor structure, which comprises a first capacitor structure located on a substrate, wherein the first capacitor structure comprises a plurality of lower electrode layers, wherein each lower electrode layer is arranged in the same direction and stacked with each other along a height direction (Z direction), and a second capacitor structure located on the first capacitor structure, wherein the second capacitor structure comprises a plurality of upper electrode layers, wherein some upper electrode layers are arranged in a first direction (X direction), and the other upper electrode layers are arranged in a second direction (Y direction), and the first direction and the second direction are perpendicular to each other.

### BACKGROUND OF THE INVENTION

### 1. Field of the Invention

The invention relates to the field of semiconductors, in particular to a composite capacitor composed of alternating polarity MOM capacitor (APMOM capacitor) and braided MOM capacitor.

### 2. Description of the Prior Art

Capacitive components play an indispensable role in the design of integrated circuits. Among them, MOM(Metal-Oxide-Metal) capacitor and MIM(Metal-Insulator-Metal) capacitor are two common capacitor structures. Although they are all made of metal and insulating layer, there are significant differences in structure, process and performance, which directly affect their choice in different application scenarios.

MOM capacitor mainly uses the oxide layer between the same layer or adjacent layers of metals as the medium to form an interdigital electrode structure. The advantage of this structure is that the process is simple, no additional mask layer is needed, and the existing metal connection layer can be fully utilized. However, because the dielectric constant of oxide layer is relatively low and the parasitic capacitance is large, the capacitance value of MOM capacitor is usually small and the frequency characteristic is relatively limited. Nevertheless, MOM capacitors are still widely used in digital circuits, such as coupling capacitors and bypass capacitors.

MIM capacitors are made of different layers of metal with an insulating layer with high dielectric constant in the middle. The advantages of this structure are large capacitance, excellent frequency characteristics and relatively stable capacitance. However, the manufacturing process of MIM capacitor is relatively complicated, which requires additional masking layer and manufacturing steps. In addition, the insulation layer with high dielectric constant may introduce large leakage current, which will affect the performance of the capacitor. MIM capacitors are usually used in analog circuits, radio frequency circuits and other occasions that require high accuracy of capacitance values.

### SUMMARY OF THE INVENTION

The invention provides a capacitor structure, which comprises a first capacitor structure located on a substrate, wherein the first capacitor structure is a metal-oxide-metal (MOM) capacitor structure and comprises a plurality of lower electrode layers, wherein each lower electrode layer is arranged in the same direction and stacked with each other along a height direction (Z direction), and a second capacitor structure located on the first capacitor structure, wherein the second capacitor structure is a metal-oxide-metal (MOM) capacitor structure, and comprises a plurality of upper electrode layers, wherein a part of the upper electrode layers in the multilayer upper electrode layers are arranged in a first direction (X direction), the other part of the upper electrode layers are arranged in a second direction (Y direction), the first direction and the second direction are perpendicular to each other, and the upper electrode layer arranged in the first direction (X direction) and the upper electrode layer arranged in the second direction (Y direction) are alternately stacked along the height direction (Z direction).

The invention also provides a manufacturing method of a capacitor structure, which comprises forming a first capacitor structure on a substrate, wherein the first capacitor structure is a metal-oxide-metal (MOM) capacitor structure and comprises a plurality of lower electrode layers, wherein each lower electrode layer is arranged in the same direction and stacked along a height direction (Z direction), and forming a second capacitor structure located on the first capacitor structure, wherein the second capacitor structure is a metal-oxide-metal (MOM) capacitor structure, and comprises a plurality of upper electrode layers, wherein a part of the upper electrode layers in the multilayer upper electrode layers are arranged in a first direction (X direction), the other part of the upper electrode layers are arranged in a second direction (Y direction), the first direction and the second direction are perpendicular to each other, and the upper electrode layer arranged in the first direction (X direction) and the upper electrode layer arranged in the second direction (Y direction) are alternately stacked along the height direction (Z direction).

The invention is characterized by providing a composite capacitor structure, which is respectively composed of an alternating polarity MOM capacitor (APMOM capacitor) at the lower part and a woven MOM capacitor at the upper part. Among them, the APMOM capacitor has higher overlapping area and capacitance value, while the woven MOM capacitor has more flexible wiring and simple process steps, so the composite capacitor of the invention combines these two kinds of MOM capacitors and can obtain the advantages of these two kinds of MOM capacitors respectively. Specifically, the APMOM capacitor can be used in the lower structure of semiconductor devices to improve the capacitance value, while the woven MOM capacitor can have the advantages of flexible routing direction and reduced process difficulty in the upper structure. Therefore, this novel composite capacitor design exhibits a higher capacitance value, simpler manufacturing process, and seamless integration with current technologies.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic diagram of overlapping patterns in the top view of an alternating polarity MOM(APMOM) capacitor among the composite capacitors of the present invention.

FIG. 2 is a schematic diagram showing the arrangement structure of an alternating polarity MOM(APMOM) capacitor in FIG. 1.

FIG. 3 shows a schematic diagram of overlapping patterns in the top view of a woven MOM capacitor among the composite capacitors of the present invention.

FIG. 4 is a schematic diagram showing the arrangement structure of the woven MOM capacitor of FIG. 3.

FIG. 5 is a schematic diagram showing a top view pattern overlapping of a composite capacitor according to an embodiment of the present invention.

FIG. 6 is a schematic diagram showing the arrangement structure of the composite capacitor of FIG. 5.

FIG. 7 is a schematic diagram showing a top view pattern overlapping of a composite capacitor according to another embodiment of the present invention.

FIG. 8 is a schematic diagram showing the arrangement structure of the composite capacitor of FIG. 7.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,”“an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,”“upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and metal layers (in which contacts, interconnect lines, and/or vias are formed) and one or more dielectric layers.

As mentioned above, capacitive elements are widely used in integrated circuit design. Among them, MOM (Metal-Oxide-Metal) capacitor can be made together with the conductor layer of electronic components, so MOM capacitor is often used as the main capacitor element in electronic components with small volume.

In an embodiment of the present invention, a composite MOM capacitor structure is provided, which is mainly composed of two parts, namely, an alternate polarity metal-oxide-metal capacitor located in the lower layer, also known as APMOM capacitor, and a woven MOM capacitor located in the upper layer, also known as woven Mom capacitor. In some embodiments, the APMOM capacitors are located in the first three layers of a semiconductor stacked structure, for example, and the woven MOM capacitors are used in structures above the fourth layer, but the number of layers here is only an example and the present invention is not limited to this. Among them, the structure and arrangement of the APMOM capacitor and the woven MOM capacitor are slightly different, and the following will introduce these two kinds of MOM capacitor structures respectively.

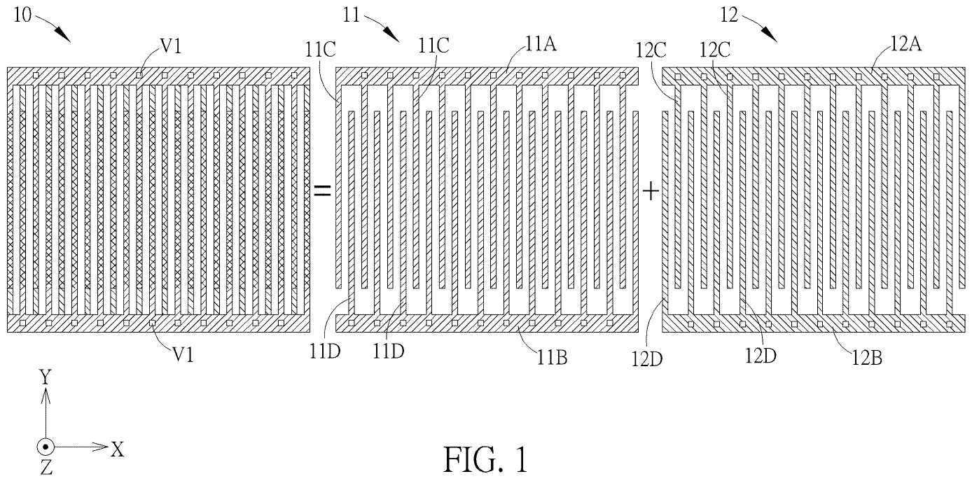

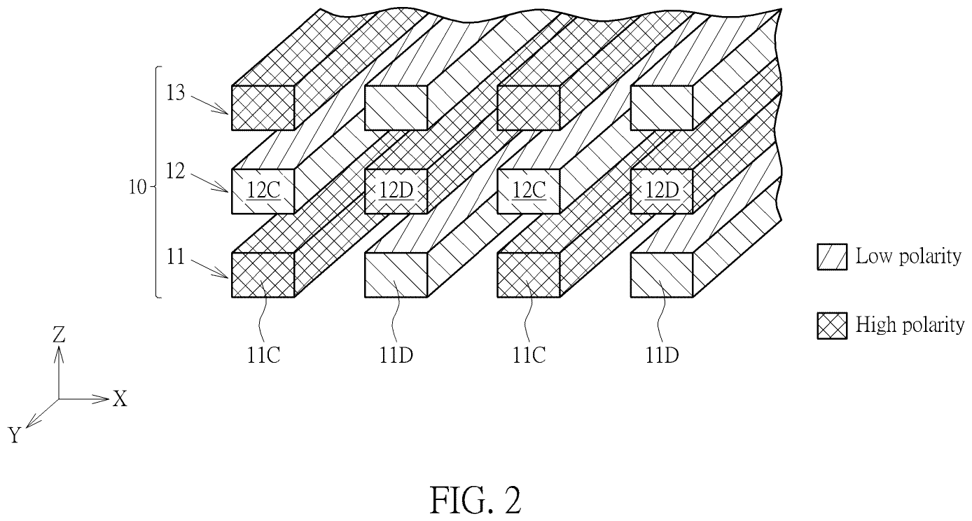

FIG. 1 shows a schematic diagram of overlapping patterns in the top view of an alternating polarity MOM(APMOM) capacitor among the composite capacitors of the present invention, and FIG. 2 shows a schematic diagram of the arrangement structure of an alternating polarity MOM (APMOM) capacitor in FIG. 1. As shown in FIG. 1 and FIG. 2, the APMOM capacitor 10 of the present invention includes a plurality of stacked lower metal layers, and here, the lower metal layer 11 and the lower metal layer 12 are described as examples, wherein the lower metal layer 11 and the lower metal layer 12 are stacked with some areas overlapping with each other. It is worth noting that although two lower metal layers (namely, the lower metal layer 11 and the lower metal layer 12) are described here, in fact, the present invention is not limited to the number of the lower metal layers. If the APMOM capacitor 10 contains more than two lower metal layers, it is within the scope of the present invention.

It is worth noting that the lower metal layer 11 and the lower metal layer 12 are stacked with each other, and some areas overlap with each other. For example, the lower metal layer 12 may be stacked above the lower metal layer 11, that is, the lower metal layer 12 and the lower metal layer 11 partially overlap in the Z axis direction. In FIG. 1, a lower metal layer 11 is shown in the middle region and a lower metal layer 12 is shown in the right region, and the APMOM capacitor 10 on the left is a schematic diagram after the lower metal layer 11 and the lower metal layer 12 are stacked.

The lower metal layer 11 comprises two main shaft electrodes 11A and 11B and a plurality of branch electrodes 11C and 11D arranged in parallel with each other, wherein the main shaft electrode 11A and the main shaft electrode 11B are arranged along a first direction (for example, X direction), and are respectively located near the upper position and the lower position in FIG. 1, and the plurality of branch electrodes 11C and 11D are arranged along a second direction (for example, Y direction), wherein each branch electrode 11C is connected with the main shaft electrode 11A located near the upper position, and each branch electrode 11c In addition, as viewed in the X direction, the branch electrodes 11C and 11D are alternately arranged, for example, in the order of the branch electrode 11C, the branch electrode 11D, the branch electrode 11C, and the branch electrode 11d. The lengths of the branch electrode 11C and the branch electrode 11D in the Y direction are preferably the same as each other. Here, the two main shaft electrodes 11A and 11B and the branch electrodes 11C and 11D are made of materials with good conductivity (such as metal) to form electrode patterns. Therefore, the lower metal layer 11 includes two main shaft electrodes 11A and 11B and branch electrodes 11C and 11D made of conductive materials, and forms an interdigital electrode pattern. Wherein, the interdigital electrode pattern is located in a dielectric layer (not shown), and the interdigital electrode pattern is used as the conductive layer of the MOM capacitor structure, and the dielectric layer is used as the oxide layer of the MOM capacitor structure.

In addition, the two main shaft electrodes 11A and 11B included in the lower metal layer 11 are respectively connected with different polarities, for example, the main shaft electrode 11A is connected to a high polarity signal, and the main shaft electrode 11B is connected to a low polarity signal, so each branch electrode 11C connected with the main shaft electrode 11A will also maintain a high polarity, and on the other hand, each branch electrode 11D connected with the main shaft electrode 11B will also maintain a low polarity. Seen from the X direction, each branch electrode 11C and each branch electrode 11D are staggered, so each branch electrode is also arranged in the order of high polarity, low polarity, high polarity, low polarity, etc.

As for the lower metal layer 12, it has a structure similar to that of the lower metal layer 11, wherein the lower metal layer 12 includes two main shaft electrodes 12A and 12B and a plurality of branch electrodes 12C and 12D arranged in parallel with each other, wherein the main shaft electrode 12A and the main shaft electrode 1B are arranged along a first direction (for example, the X direction) and are respectively located at an upper position and a lower position in FIG. 1. A plurality of branch electrodes 12C and a plurality of branch electrodes 12D are arranged along the second direction (for example, Y direction), wherein each branch electrode 12C is connected to the main shaft electrode 12A located near the upper position, and each branch electrode 12D is connected to the main shaft electrode 12D located near the lower position. In addition, as viewed in the X direction, the branch electrodes 12C and 12D are alternately arranged, for example, in the order of the branch electrode 12C, the branch electrode 12D, the branch electrode 12C, the branch electrode 12D ... from left to right. The lengths of the branch electrode 12C and the branch electrode 12D in the Y direction are preferably the same as each other. Here, the two main shaft electrodes 12A, 12B and the branch electrodes 12C, 12D are all made of materials with good conductivity (such as metal), so the lower metal layer 12 includes two main shaft electrodes 12A, 12B and the branch electrodes 12C, 12D made of conductive materials, and forms an interdigital electrode pattern. Wherein, the interdigital electrode pattern is located in a dielectric layer (not shown), and the interdigital electrode pattern is used as the conductive layer of the MOM capacitor structure, and the dielectric layer is used as the oxide layer of the MOM capacitor structure.

In addition, the two main shaft electrodes 12A and 12B included in the lower metal layer 12 are connected to different polarities, for example, the main shaft electrode 12A is connected to a low polarity signal and the main shaft electrode 12B is connected to a high polarity signal, so each branch electrode 12C connected to the main shaft electrode 12A will also maintain low polarity, and on the other hand, each branch electrode 12D connected to the main shaft electrode 12B will also maintain high polarity. As viewed from the X direction, each branch electrode 12C and each branch electrode 12D are alternately arranged, so each branch electrode is also arranged in the order of low polarity, high polarity, low polarity, high polarity, etc.

Reference can be made to FIG. 2, for any branch electrode (11C, 11D, 12C, or 12D) included in the lower metal layer 11 or the lower gold layer 12, the adjacent branch electrodes in the X and Z directions have opposite polarity to itself. In other words, if one branch electrode 11C with high polarity is selected, the left and right branch electrodes 11D in the X direction are low polarity, and the upper branch electrode 12C is also low polarity. On the other hand, if one branch electrode 11D with low polarity is selected, the left and right branch electrodes 11C in the X direction have high polarity, and the upper branch electrode 12D also has high polarity. For the sake of clarity, in FIG. 2, different patterns are used to represent high polarity and low polarity respectively. In addition, FIG. 2 shows that another lower metal layer 13 is stacked on the lower metal layer 12, which means that the APMOM capacitor 10 can include more lower electrode layers besides the lower metal layer 11 and the lower metal layer 12. The pattern features of the lower metal layer 13 may be the same as or similar to those of the lower metal layer 11, so the detailed features are not repeated here.

In addition, the APMOM capacitor 10 may also include a plurality of contact plugs V1, where the contact plugs V1 are used to connect different metal electrode layers with the same polarity (e.g., the same high polarity or the same low polarity). Therefore, the signal output from the signal source can be conducted to each metal electrode layer. In this embodiment, because the line width of the main shaft electrodes is relatively large, each contact plug V1 and each main shaft electrode 11A/11B/12A/12B overlap each other, so that the contact plug V1 can be easily aligned with each main shaft electrode 11A/11B/12A/12B without being offset, but the present invention is not limited to this, and the position of the contact plug V1 can be adjusted as required in other embodiments of the present invention.

In addition, the manufacturer can reduce the line width and spacing of the APMOM capacitor 10 formed in FIG. 1 as much as possible, increase the element density and reduces the overall volume of the element, so as to achieve miniaturization. In this embodiment, each lower metal layer in the APMOM capacitor 10 can be formed by two exposure and development steps (using two masks respectively). For example, the main shaft electrode 11A and the branch electrode 11C of the lower metal layer 11 can be formed by one exposure and development process, and then the main shaft electrode 11B and the branch electrode 11D of the lower metal layer 11 can be formed by another exposure and development process. In this way, the pattern of the lower metal layer 11 is composed by two exposure and development steps, and the pattern density of the lower metal layer 11 can be improved. Similarly, the remaining lower metal layer 12 and the lower metal layer 13, etc. are also preferably formed by two exposure and development steps. In this embodiment, taking the 14 nm process as an example, the minimum line width of the lower metal layer 11 and the minimum spacing between the branch electrodes (or critical dimension) are about 36 nm, but the present invention is not limited to this. With the development of technology, the above minimum line width and minimum spacing may continue to decrease.

As shown in FIG. 1 and FIG. 2, the APMOM capacitor 10 is characterized in that the lower metal layers are all arranged in the same direction. Specifically, the arrangement direction of the main shaft electrodes 11A/11B of the lower metal layer 11 is the same as that of the main shaft electrodes 12A/12B of the lower metal layer 12, and the arrangement direction of the branch electrodes 11C/11D of the lower metal layer 11 is the same as that of the branch electrodes 12C/12D of the lower metal layer 12. Under this arrangement, because most areas of each branch electrode overlap each other, the overlapping area between different lower metal layers is larger. Since the capacitance value of MOM capacitor is proportional to the overlapping area between electrodes, that is, the larger the overlapping area between electrodes, the larger the capacitance value of MOM capacitor, so the APMOM capacitor 10 has a larger capacitance value, which can store more charges in a limited area and has higher efficiency.

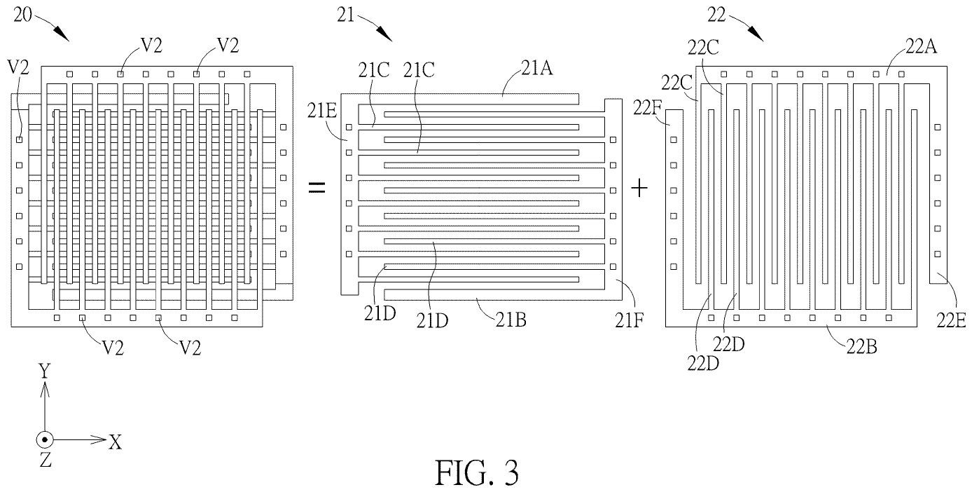

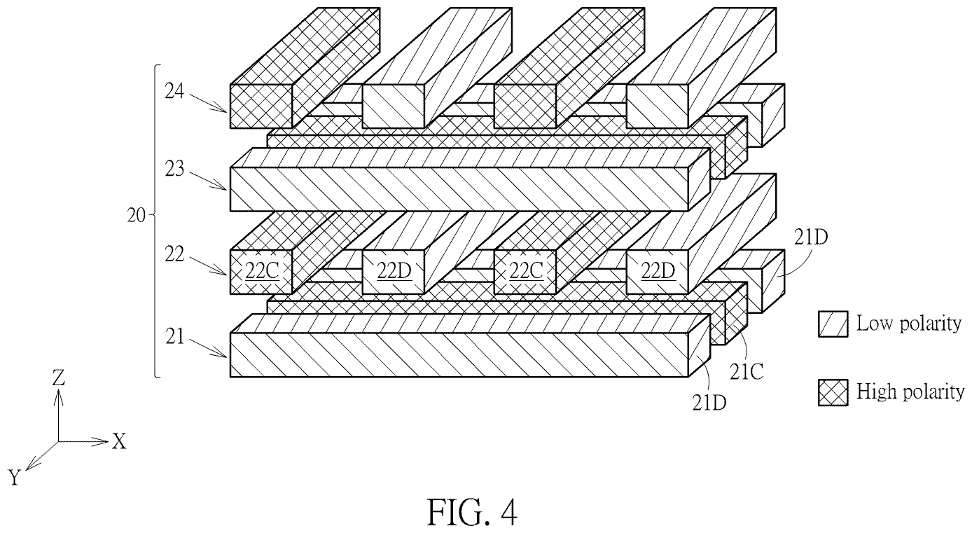

FIG. 3 shows a schematic diagram of overlapping patterns in the top view of a woven MOM capacitor among the composite capacitors of the present invention. FIG. 4 shows a schematic diagram of the arrangement structure of a woven MOM capacitor of FIG. 3. As shown in FIG. 3 and FIG. 4, the woven MOM capacitor 20 of the present invention includes a plurality of stacked upper metal layers. Here, the upper metal layer 21 and the upper metal layer 22 are described as examples, wherein the upper metal layer 21 and the upper metal layer 22 are stacked with some areas overlapping each other. It is worth noting that although two upper metal layers (namely, the upper metal layer 21 and the upper metal layer 22) are described here, in fact, the present invention is not limited to the number of upper metal layers. If the woven MOM capacitor 20 includes more than two upper metal layers, it is also within the scope of the present invention.

It is worth noting that the upper metal layer 21 and the upper metal layer 22 are stacked with each other, and some areas overlap with each other. For example, the upper metal layer 22 can be stacked above the upper metal layer 21, that is, the upper metal layer 22 and the upper metal layer 21 partially overlap in the Z axis direction. In FIG. 3, the upper metal layer 21 is shown in the middle region and the upper metal layer 22 is shown in the right region, and the woven MOM capacitor 20 on the left is a schematic diagram after the upper metal layer 21 and the upper metal layer 22 are stacked.

The upper metal layer 21 includes an L-shaped main shaft electrode composed of a main shaft electrode 21A and a main shaft electrode 21E, and another L-shaped main shaft electrode composed of a main shaft electrode 21B and a main shaft electrode 21F, and a plurality of parallel branch electrodes 21C and 21D are respectively connected to the main shaft electrode 21E and the main shaft electrode 21F. The main shaft electrode 21A and the main shaft electrode 21B are arranged along a first direction (for example, X direction), the main shaft electrode 21E and the main shaft electrode 21F are arranged along a second direction (Y direction), and the branch electrodes 21C and 21D are arranged along the first direction (for example, X direction). In addition, as viewed in the Y direction, the branch electrodes 21C and 21D are alternately arranged, for example, in the order of branch electrode 21C, branch electrode 21D, branch electrode 21C, branch electrode 21D . . . from top to bottom. The lengths of the branch electrode 21C and the branch electrode 21D in the X direction are preferably the same as each other. Here, the main shaft electrodes 21A, 21B, 21E, 21F and the branch electrodes 21C, 21D are all made of materials with good electrical conductivity (such as metal), so the upper metal layer 21 includes the main shaft electrodes 21A, 21B, 21E, 21F and the branch electrodes 21C, 21D made of conductive materials, and forms an interdigital electrode pattern. Wherein the interdigital electrode pattern is located in a dielectric layer (not shown), and the interdigital electrode pattern is used as the conductive layer of the MOM capacitor structure, and the dielectric layer is used as the oxide layer of the MOM capacitor structure.

In addition, the two L-shaped main shaft electrodes contained in the upper metal layer 21 (that is, the main shaft electrode 21A and the main shaft electrode 21E form one L-shaped main shaft electrode, and main shaft electrode 21B and main shaft electrode 21F form the other L-shaped main shaft electrode) are respectively connected with different polarities, for example, main shaft electrode 21E is connected to a high polarity signal, while main shaft electrode 21F is connected to a low polarity signal, so each branch electrode 21C connected to main shaft electrode 21E will maintain high polarity, and vice versa. As viewed from the Y direction, each branch electrode 21C and each branch electrode 21D are staggered, so each branch electrode is also arranged in the order of high polarity, low polarity, high polarity, low polarity.

As for the upper metal layer 22, it has a similar structure to the upper metal layer 21, but it is worth noting that the arrangement directions of the upper metal layer 22 and the upper metal layer 21 are different. Specifically, the arrangement direction of each branch electrode in the upper metal layer 22 and the arrangement direction of each branch electrode in the upper metal layer 21 are perpendicular to each other on the XY plane. Taking this embodiment as an example, the upper metal layer 22 includes an L-shaped main shaft electrode composed of a main shaft electrode 22A and a main shaft electrode 22E, and another L-shaped main shaft electrode composed of a main shaft electrode 22B and a main shaft electrode 22F, and a plurality of parallel branch electrodes 22C and 22D are respectively connected with the main shaft electrode 22E and the main shaft electrode 22F. The main shaft electrode 22A and the main shaft electrode 22B are arranged along a first direction (for example, X direction), the main shaft electrode 22E and the main shaft electrode 22F are arranged along a second direction (for example, Y direction), and the branch electrodes 22C and 22D are arranged along a second direction (for example, Y direction). In addition, as viewed in the X direction, the branch electrodes 22C and 22D are alternately arranged, for example, in the order of the branch electrode 22D, the branch electrode 22C, the branch electrode 22D, the branch electrode 22C, . . . from left to right. The lengths of the branch electrode 22C and the branch electrode 22D in the Y direction are preferably the same as each other. Here, the main shaft electrodes 22A, 22B, 22E, 22F and the branch electrodes 22C, 22D are all made of materials with good conductivity (such as metal), so the upper metal layer 22 includes the main shaft electrodes 22A, 22B, 22E, 22F and the branch electrodes 22C, 22D made of conductive materials, and forms an interdigital electrode pattern. Wherein, the interdigital electrode pattern is located in a dielectric layer (not shown), and the interdigital electrode pattern is used as the conductive layer of the MOM capacitor structure, and the dielectric layer is used as the oxide layer of the MOM capacitor structure.

In addition, the two L-shaped main shaft electrodes contained in the upper metal layer 22 (namely, the main shaft electrode 22A and the main shaft electrode 22E form one L-shaped main shaft electrode, and the main shaft electrode 22B and the main shaft electrode 22F form the other L-shaped main shaft electrode) are respectively connected with different polarities, for example, the main shaft electrode 22A is connected to a high-polarity signal, and the main shaft electrode 22B is connected to a low-polarity signal, so each branch electrode 22C connected to the main shaft electrode 22A will also maintain a high polarity, and conversely, each branch electrode connected to the main shaft electrode 22B. As viewed from the X direction, each branch electrode 22C and each branch electrode 22D are staggered, so each branch electrode is also arranged in the order of low polarity, high polarity, low polarity, high polarity, etc.

Reference can be made to FIG. 4 together, for any branch electrode (21C, 21D, 22C, or 22D) included in the upper metal layer 21 or the lower gold layer 22, the adjacent branch electrodes in the XY plane have opposite polarity to itself. In other words, if one branch electrode 21C with high polarity is selected, the adjacent branch electrode 21D in the XY plane direction has low polarity. On the other hand, if one branch electrode 21D with low polarity is selected, the adjacent branch electrode 21C in the XY plane direction has high polarity. As described above, the arrangement direction of the branch electrodes 21C/21D and the arrangement direction of the branch electrodes 22C/22D are perpendicular to each other. For the sake of clarity, in FIG. 4, different patterns are used to represent high polarity and low polarity respectively. In addition, FIG. 4 shows that two other upper metal layers 23 and 24 are stacked above the upper metal layer 22, which means that the woven MOM capacitor 20 can include more upper electrode layers besides the upper metal layer 21 and the upper metal layer 22. The pattern features of the upper metal layer 23 and the upper metal layer 24 are similar to those of the upper metal layer 21 and the upper metal layer 22, respectively, so the detailed features are not repeated here.

In addition, the woven MOM capacitor 20 may also include a plurality of contact plugs V2, where the contact plugs V2 are used to connect different metal electrode layers with the same polarity (e.g., the same high polarity or the same low polarity). Therefore, the signal output from the signal source can be conducted to each metal electrode layer. In this embodiment, because the line width of the main shaft electrodes is relatively large, each contact plug V2 overlaps with each main shaft electrode 21A/21B/21E/21F/22A/22B/22E/22F, so that the contact plug V2 is easily aligned with each main shaft electrode 21A/21B/21E/21F/22A/22B/22E/22F without offset, but the present invention is not limited to this. In addition, since each main shaft electrode is L-shaped, the contact plug V2 can connect different upper metal layers in the Z direction even if the arrangement directions of adjacent upper metal layers are perpendicular to each other.

In addition, it is worth noting that the woven MOM capacitor 20 is stacked above the APMOM capacitor 10, and the line width and the spacing between branch electrodes of the woven MOM capacitor 20 may be looser than that of APMOM capacitor 10, because in the semiconductor manufacturing process, Several layers of structures closer to the substrate (i.e., where the APMOM capacitor 10 is located) may form more high-density electronic components (such as transistors), while the upper structure farther away from the substrate (i.e., where the woven MOM capacitor 20 is located) is mainly used to form connecting elements such as wires. Therefore, in the upper structure, the component density is usually low, which can allow looser line width and spacing. Taking this embodiment as an example, the line width (or spacing between branch electrodes) of the woven MOM capacitor 20 is about 1.25 times that of the APMOM capacitor 10, but the present invention is not limited to this. If the minimum line width of the APMOM capacitor 10 is 36 nm, the minimum line width of the woven MOM capacitor 20 is about 45 nm. In addition, because the minimum line width of the woven MOM capacitor 20 is relatively large, each upper metal layer in the woven MOM capacitor 20 can be made by a single exposure and development process, and it is not necessary to make the lower metal layer by two exposure and development processes, so that the process steps can be saved.

As shown in FIGS. 3 and 4, the woven MOM capacitor 20 is characterized in that adjacent upper metal layers are arranged in the vertical direction. Specifically, the arrangement direction of the branch electrodes 21C/21D of the upper metal layer 21 is perpendicular to the arrangement direction of the branch electrodes 22C/22D of the upper metal layer 22. In this arrangement, although the overlap area between the upper metal layers is smaller than that between the lower metal layers in the aforementioned APMOM capacitor 10, but the routing direction of the upper metal layers is more flexible, making it suitable for forming an upper structure primarily consisting of conductive lines or wires.

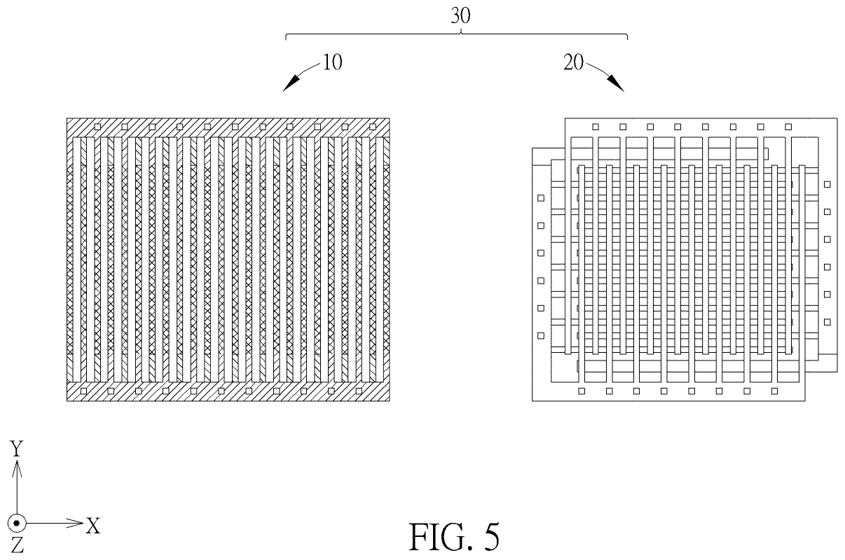

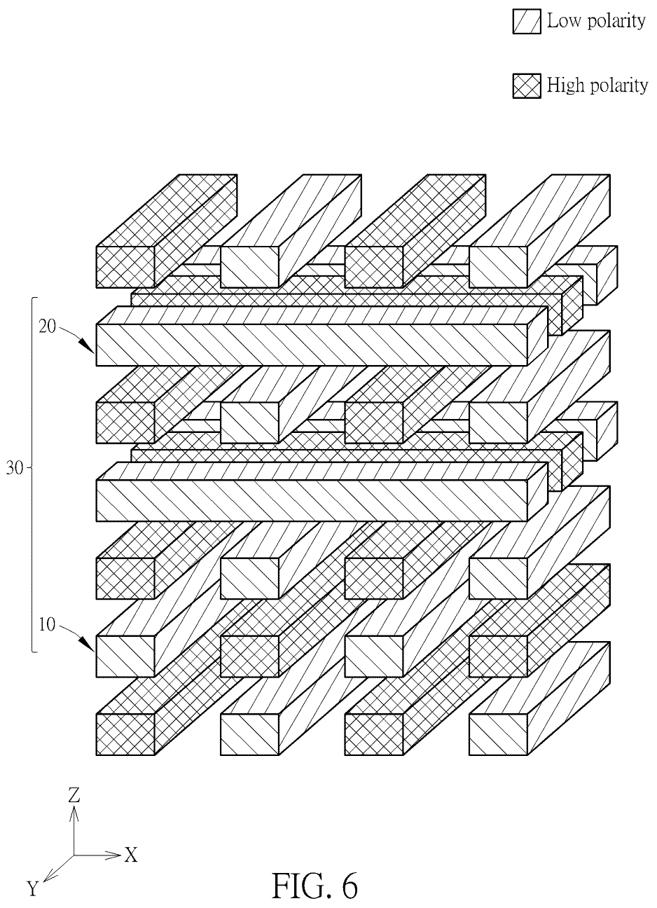

FIG. 5 shows a schematic diagram of a composite capacitor in an embodiment of the present invention, and FIG. 6 shows a schematic diagram of the arrangement structure of the composite capacitor in FIG. 5. As shown in FIG. 5 and FIG. 6, the composite capacitor 30 of the present invention comprises an APMOM capacitor 10 below and a woven MOM capacitor 20 stacked above, wherein the APMOM capacitor 10 and the woven MOM capacitor 20 are connected with each other through a contact plug and other structures. The characteristics of the APMOM capacitor 10 and the woven MOM capacitor 20 have been described in the above paragraphs, so they are not repeated here. In addition, in this embodiment, the arrangement direction of the branch electrode of the lowermost layer of the woven MOM capacitor 20 (i.e., the upper metal layer closest to the APMOM capacitor 10) is perpendicular to the arrangement direction of the branch electrode of the APMOM capacitor 10.

It is worth noting that in this embodiment, the woven MOM capacitor 20 is stacked above the APMOM capacitor 10, and the two capacitors are preferably electrically connected by a contact plug, so as to transmit the high polarity signal or the low polarity signal sent by the signal source to the electrode. As mentioned in the previous paragraph, the APMOM capacitor 10 has the advantage of higher overlapping area and therefore higher unit capacitance, while woven MOM capacitor 20 has the advantage of higher routing flexibility and fewer manufacturing steps. Therefore, the composite capacitor 30 of the present invention combines the APMOM capacitor 10 and the woven MOM capacitor 20. According to the applicant's experimental results, the capacitance value of the composite capacitor 30 of the present invention is increased by about 2%~8% compared with the embodiment in which the woven MOM capacitor is completely used as the capacitor in the semiconductor structure. Therefore, under the condition of compatibility with the prior art, the capacitance value of the MOM capacitor is improved.

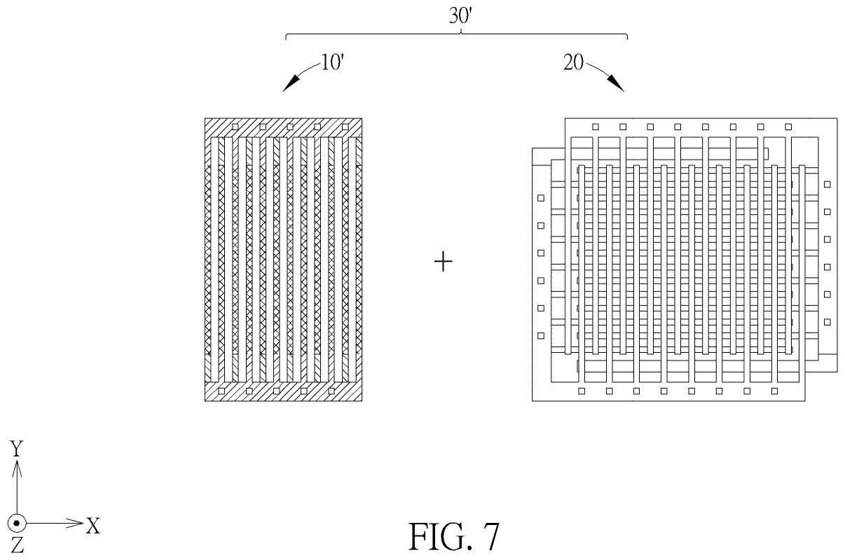

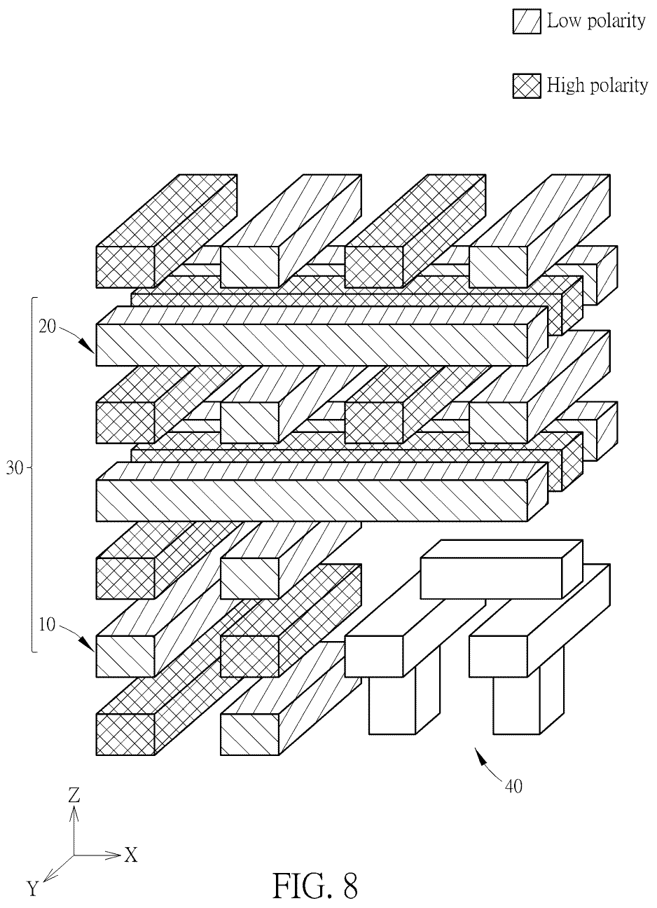

FIG. 7 shows a schematic diagram of overlapping patterns in the top view of a composite capacitor according to another embodiment of the present invention, and FIG. 8 shows a schematic diagram of the arrangement structure of the composite capacitor of FIG. 7. As shown in FIG. 7 and FIG. 8, in another embodiment of the present invention, a composite capacitor 30′ can be formed by stacking an APMOM capacitor 10′ and a woven MOM capacitor 20. The characteristics of the woven MOM capacitor 20 here have been described in the above paragraphs, the main difference between the APMOM capacitor 10′ and the aforementioned APMOM capacitor 10 is that the APMOM capacitor 10′ has a smaller area, and the other features are the same, so they are not repeated here. The main difference between this embodiment and the above embodiment is that the area of the APMOM capacitor 10′ is smaller than that of the woven MOM capacitor 20. As shown in FIG. 8, electronic components 40 (such as transistors, etc., but not limited to this) on the substrate occupy a part of the substrate area. At this time, the remaining area on the substrate can be used to form the APMOM capacitor 10′, and then the woven MOM capacitor 20 is continuously formed and stacked on the APMOM capacitor 10′ and the electronic components 40. In this embodiment, the remaining area on the substrate can be fully utilized to form the APMOM capacitor 10′ in the area other than the area occupied by the electronic component 40, so that the process space can be saved and the purpose of miniaturization of the component can be achieved.

According to the above description and drawings, the present invention provides a capacitor structure 30, which comprises a first capacitor structure (the APMOM capacitor 10) located on a substrate, wherein the first capacitor structure 10 is a metal-oxide-metal (MOM) capacitor structure, and comprises a plurality of lower electrode layers 11/12, wherein each lower electrode layer 11/12 is arranged in the same direction and along a height direction (Z direction). And a second capacitor structure (the woven MOM capacitor) 20 located on the first capacitor structure 10, wherein the second capacitor structure 20 is a metal-oxide-metal (MOM) capacitor structure, and comprises a plurality of upper electrode layers 21/22, wherein a part of the upper electrode layers 21/22 (for example, the upper electrode layer 21) are arranged in the first direction (X direction), another part of the upper electrode layer (for example, the upper electrode layer 22) is arranged in a second direction (Y direction), the first direction (X direction) is perpendicular to the second direction (Y direction), and the upper electrode layer 21 arranged in the first direction (X direction) and the upper electrode layer 22 arranged in the second direction (Y direction) are alternately stacked along the height direction (Z direction).

In some embodiments of the present invention, each lower electrode layer 11/12 includes two first comb patterns (for example, 11A/11B or 12A/12B), wherein each first comb pattern includes a main shaft electrode 11A and a plurality of branch electrodes 11C, and each branch electrode 11C is arranged along the second direction (Y direction).

In some embodiments of the present invention, in the two first comb patterns included in the lower electrode layer, the main shaft electrodes 11A are arranged along the first direction (X direction), and the main shaft electrodes 11A present a strip pattern.

In some embodiments of the present invention, the branch electrodes 11C/11D in the two first comb patterns included in the lower electrode layer 11 are alternately arranged to form an interdigital electrode pattern.

In some embodiments of the present invention, among the multilayer upper electrode layers 21/22 included in the second capacitor structure 20, the upper electrode layer 21 closest to the first capacitor structure 10 is defined as a junction electrode layer (i.e., the upper electrode layer 21), wherein the junction electrode layer contains a plurality of branch electrodes 21C/21D, and each branch electrode 21C/21D is arranged along the first direction (X direction).

In some embodiments of the present invention, the junction electrode layer includes two second comb patterns, and each second comb pattern includes a main shaft electrode (for example, 21A and 21E) and a plurality of branch electrodes 21C, wherein the main shaft electrode presents an L-shaped pattern.

In some embodiments of the present invention, a plurality of lower electrode layers 10 have the same first line width, and a plurality of upper electrode layers 20 contain the same second line width.

In some embodiments of the present invention, the first line width is smaller than the second line width. For example, the width of the second line is 1.25 times of the first line width, but it is not limited to this.

In some embodiments of the present invention, an area of the first capacitor structure 10 is smaller than an area of the second capacitor structure 20 when viewed from a top view (please refer to FIG. 7).

In some embodiments of the present invention, an electronic component 40 is located on the substrate and next to the first capacitor structure 10, wherein the electronic component 40 is covered by the second capacitor structure 20.

The invention also provides a manufacturing method of a capacitor structure, which comprises forming a first capacitor structure (the APMOM capacitor 10) on a substrate, wherein the first capacitor structure 10 is a metal-oxide-metal (MOM) capacitor structure and comprises a plurality of lower electrode layers 11/12, wherein each lower electrode layer 11/12 is arranged in the same direction and stacked with each other along a height direction (Z direction). And forming a second capacitor structure (the woven MOM capacitor) 20 located on the first capacitor structure 10, wherein the second capacitor structure 20 is a metal-oxide-metal (MOM) capacitor structure, and comprises a plurality of upper electrode layers 21/22, wherein a part of the upper electrode layers 21/22 (for example, the upper electrode layer 21) are arranged in the first direction (X direction), another part of the upper electrode layer (for example, the upper electrode layer 22) is arranged in a second direction (Y direction), the first direction (X direction) is perpendicular to the second direction (Y direction), and the upper electrode layer 21 arranged in the first direction (X direction) and the upper electrode layer 22 arranged in the second direction (Y direction) are alternately stacked along the height direction (Z direction).

To sum up, the invention is characterized by providing a composite capacitor structure, which is respectively composed of an alternating polarity MOM capacitor (APMOM capacitor) at the lower part and a woven MOM capacitor at the upper part. Among them, the APMOM capacitor has higher overlapping area and capacitance value, while the woven MOM capacitor has more flexible wiring and simple process steps, so the composite capacitor of the invention combines these two kinds of MOM capacitors and can obtain the advantages of these two kinds of MOM capacitors respectively. Specifically, the APMOM capacitor can be used in the lower structure of semiconductor devices to improve the capacitance value, while the woven MOM capacitor can have the advantages of flexible routing direction and reduced process difficulty in the upper structure. Therefore, this novel composite capacitor design exhibits a higher capacitance value, simpler manufacturing process, and seamless integration with current technologies.

Those skilled in the art will readily observe that numerous modifications and

alterations of the device and method may be made while retaining the teachings of the invention. Accordingly, the above disclosure should be construed as limited only by the metes and bounds of the appended claims.

What is claimed is:

1. A capacitor structure comprising:
a first capacitor structure located on a substrate, wherein the first capacitor structure is a metal-oxide-metal (MOM) capacitor structure and comprises a plurality of lower electrode layers, wherein each lower electrode layer is arranged in the same direction and stacked along a height direction (Z direction); and
a second capacitor structure located on the first capacitor structure, wherein the second capacitor structure is a metal-oxide-metal (MOM) capacitor structure, and comprises a plurality of upper electrode layers, wherein a part of the upper electrode layers in the multilayer upper electrode layers are arranged in a first direction (X direction), the other part of the upper electrode layers are arranged in a second direction (Y direction), the first direction and the second direction are perpendicular to each other, and the upper electrode layer arranged in the first direction (X direction) and the upper electrode layer arranged in the second direction (Y direction) are alternately stacked along the height direction (Z direction).

2. The capacitor structure according to claim 1, wherein each lower electrode layer comprises two first comb patterns, wherein each first comb pattern comprises a main shaft electrode and a plurality of branch electrodes, and each branch electrode is arranged along the second direction (Y direction).

3. The capacitor structure according to claim 2, wherein in the two first comb patterns included in the lower electrode layer, the main shaft electrodes are arranged along the first direction (X direction), and the main shaft electrodes present a strip pattern.

4. The capacitor structure according to claim 2, wherein the branch electrodes in the two first comb patterns included in the lower electrode layer are alternately arranged to form an interdigital electrode pattern.

5. The capacitor structure according to claim 2, wherein the upper electrode layer closest to the first capacitor structure among the plurality of upper electrode layers included in the second capacitor structure is defined as a junction electrode layer, wherein the junction electrode layer includes a plurality of branch electrodes, and each branch electrode is arranged along the first direction (X direction).

6. The capacitor structure according to claim 5, wherein the junction electrode layer comprises two second comb patterns, and each second comb pattern comprises a main shaft electrode and a plurality of branch electrodes, wherein the main shaft electrode presents an L-shaped pattern.

7. The capacitor structure according to claim 1, wherein the lower electrode layers have the same first line width, and the upper electrode layers contain the same second line width.

8. The capacitor structure according to claim 7, wherein the first line width is smaller than the second line width.

9. The capacitor structure according to claim 1, wherein an area of the first capacitor structure is smaller than an area of the second capacitor structure when viewed from a top view.

10. The capacitor structure according to claim 9, further comprising an electronic component located on the substrate, and the electronic component is disposed next to the first capacitor structure, wherein the electronic component is covered by the second capacitor structure.

11. A manufacturing method of a capacitor structure, comprising:
forming a first capacitor structure on a substrate, wherein the first capacitor structure is a metal-oxide-metal (MOM) capacitor structure, and comprises a plurality of lower electrode layers, wherein each lower electrode layer is arranged in the same direction and stacked along a height direction (Z direction); and
forming a second capacitor structure located on the first capacitor structure, wherein the second capacitor structure is a metal-oxide-metal (MOM) capacitor structure, and comprises a plurality of upper electrode layers, wherein a part of the upper electrode layers in the multilayer upper electrode layers are arranged in a first direction (X direction), the other part of the upper electrode layers are arranged in a second direction (Y direction), the first direction and the second direction are perpendicular to each other, and the upper electrode layer arranged in the first direction (X direction) and the upper electrode layer arranged in the second direction (Y direction) are alternately stacked along the height direction (Z direction).

12. The manufacturing method of the capacitor structure according to claim 11, wherein each lower electrode layer comprises two first comb patterns, wherein each first comb pattern comprises a main shaft electrode and a plurality of branch electrodes, and each branch electrode is arranged along the second direction (Y direction).

13. The manufacturing method of the capacitor structure according to claim 12, wherein in the two first comb patterns included in the lower electrode layer, the main shaft electrodes are arranged along the first direction (X direction), and the main shaft electrodes present a strip pattern.

14. The manufacturing method of the capacitor structure according to claim 12, wherein the branch electrodes in the two first comb patterns included in the lower electrode layer are alternately arranged to form an interdigital electrode pattern.

15. The manufacturing method of the capacitor structure according to claim 12, wherein the upper electrode layer closest to the first capacitor structure among the plurality of upper electrode layers included in the second capacitor structure is defined as a junction electrode layer, wherein the junction electrode layer includes a plurality of branch electrodes, and each branch electrode is arranged along the first direction (X direction).

16. The manufacturing method of the capacitor structure according to claim 15, wherein the junction electrode layer comprises two second comb patterns, each of which comprises a main shaft electrode and a plurality of branch electrodes, wherein the main shaft electrode presents an L-shaped pattern.

17. The manufacturing method of the capacitor structure according to claim 11, wherein the lower electrode layers have the same first line width, and the upper electrode layers contain the same second line width.

18. The manufacturing method of the capacitor structure according to claim 17, wherein the first line width is smaller than the second line width.

19. The manufacturing method of the capacitor structure according to claim 11, wherein an area of the first capacitor structure is smaller than an area of the second capacitor structure when viewed from a top view.

20. The manufacturing method of the capacitor structure according to claim 19, further comprising forming an electronic component located on the substrate, and the electronic component is disposed next to the first capacitor structure, wherein the electronic component is covered by the second capacitor structure.
